(19) United States
(12) Patent Application Publication
(10) Pub. No.: US 2003/0227809 A1
(43) Pub. Date: Dec. 11, 2003

(54) Temperature-adjusted pre-charged reference for an integrated circuit 1T/1C ferroelectric memory

(76) Inventor: Kurt S. Schwartz, Woodland Park, CO (US)

Correspondence Address: HOGAN & HARTSON LLP, ONE TABOR CENTER, SUITE 1500, 1200 SEVENTEENTH ST, DENVER, CO, 80202, US

(21) Appl. No.: 10/163,323

(22) Filed: Jun. 5, 2002

(51) Int. Cl. G11C 7/04

(52) U.S. Cl. 365/211

(57) ABSTRACT

A temperature-dependent reference works by pre-charging a standard linear CMOS or ferroelectric reference capacitor to a pre-charge voltage that is dependent on temperature. At cold temperatures the pre-charge voltage is higher, resulting in a larger voltage on the reference bit-line. At warm temperatures the pre-charge voltage is lower, resulting in a smaller voltage on the reference bit-line. Both the precise temperature slope and offset pre-charge voltage are selectable.

### BACKGROUND OF THE INVENTION

This invention pertains to ferroelectric capacitors and integrated circuit memory devices, and, more particularly, to a temperature-compensated reference circuit for an integrated circuit ferroelectric memory.

Ferroelectric materials are used in storage node capacitors due to their electrical properties of retention, read/write endurance, and speed of the write cycle. In a typical implementation, a ferroelectric capacitor “stack” includes a platinum or iridium bottom electrode, a ferroelectric dielectric layer, and a platinum or iridium top electrode. The ferroelectric capacitor stack is then inserted into a conventional CMOS process flow with some minor modifications of the masking layers.

Referring now to FIG. 1 a hysteresis loop 38 is shown, which illustrates the electrical properties of a ferroelectric capacitor used in a typical integrated circuit ferroelectric memory. Hysteresis loop 38 is centered about the origin of a charge (Q) vs. voltage (−V, +V) graph, wherein voltage is plotted along the X-axis, and charge is plotted along the Y-axis. A ferroelectric capacitor has two stable states that can be used for data storage. These are shown as operating points 1 and 3 on hysteresis loop 38. These points represent more or less permanent stable states inside the ferroelectric material that are retained after an externally applied electrical field is removed. The act of applying an external field to a ferroelectric material or capacitor is known in the art as “poling” and is described in the seminal text on ferroelectrics entitled “Piezoelectric Ceramics” by Jaffe, Cook, and Jaffe, published in 1971. On page one of the text, the authors state that “[t]oday we know that the polarity needed to impart piezoelectric properties can be given to an originally isotropic polycrystalline ceramic, more or less permanently, by temporary application of a strong electric field. This process, called ‘poling’, is analogous to the magnetizing of a permanent magnet.”

Various charge components of hysteresis curve 38 have been identified in characterizing electrical performance of ferroelectric capacitors. A “P” charge component is defined as the charge associated with the application of an external positive voltage, and an excursion from operating point 1 to operating point 2 on hysteresis curve 38. A “U” charge component is defined as the charge associated with the application of an external positive voltage, and an excursion from operating point 3 to operating point 2 on hysteresis curve 38. An “N” charge component is defined as the charge associated with the application of an external negative voltage, and an excursion from operating point 3 to operating point 4 on hysteresis curve 38. A “D” charge component is defined as the charge associated with the application of an external negative voltage, and an excursion from operating point 1 to operating point 4 on hysteresis curve 38. The “Pa” and “Ua” charge components are “after” terms that indicate a transition on the ferroelectric hysteresis curve 38 of FIG. 1 from operating point 2 to operating point 3 after a corresponding initial P pulse or a U pulse. Similarly, the “Da” and “Na” charge components are “after” terms that indicate a transition from operating point 4 to operating point 1 after a corresponding initial D pulse or an N pulse.

Hysteresis curve 38 is generated using the “Sawyer-Tower” circuit 40 shown in FIG. 2. This circuit is well known in the ferroelectric art and is exceedingly simple in construction and operation. The basic components of this circuit are an input voltage or pulse generator, designated “Vin” in FIG. 2, a ferroelectric capacitor under test CF, a linear load capacitor CL, and an output pin 42. The output pin 42 is monitored by a voltmeter or oscilloscope (not shown in FIG. 2) as required. In order to make charge measurements and to generate a hysteresis curve, the capacitance of the load capacitor CL must be made much greater than the capacitance of the ferroelectric capacitor CF under test. In this way, most of the input voltage will be dropped across the capacitor under test The output voltage, however, can be related to the charge liberated by the ferroelectric capacitor under test using the well-known charge equation Q=CV, wherein “C” is equal to CL.

The operation of the “Sawyer-Tower” circuit 40 and corresponding hysteresis loop 38 is further explained at pages 37-38 of the Jaffe, Cook, and Jaffe text referred to above. “The commonly accepted criterion of ferroelectricity is a hysteresis loop on a D-E display. This is usually done with a cathode-ray oscillograph. (footnote omitted) Briefly, the method consists of applying an alternating voltage and relating the stored charge to the instantaneous voltage. (figure similar to FIG. 2 omitted) A large integrating capacitor is placed in series with the sample. The voltage across it measures the charge stored on the test sample and is conventionally displayed as the vertical deflection of an oscillograph. The applied voltage is displayed as the horizontal deflection.”

A prior art reference cell 10 for an integrated circuit 1T/1C ferroelectric memory is shown in FIG. 3. Reference cell 10 includes an N-channel transistor 12 coupled between the VDD supply voltage source and a reference capacitor CREF. The reference capacitor can either be a linear capacitor, or a “Da”-type ferroelectric capacitor operated in a linear region as explained above with respect to FIG. 1. The C_{REF} reference capacitor is charged to VDD through the operation of the REFPCB gate control signal of transistor 12. The charge on the C_{REF} capacitor is shared with the BL bit-line capacitance C_{BL} to form an intermediate reference voltage through the action of the REFWL control signal coupled to the gate on N-channel transistor 14. The BL bit line can be periodically reset to zero volts through the action of N-channel transistor 16 and control signal BLPC as required.

One of the problems associated with reference cell 10 is that the “Da”-type reference voltage generated by the linear portion of a ferroelectric capacitor hysteresis loop is generally constant with respect to temperature, but the corresponding one and zero levels of a ferroelectric memory cell generally have a marked negative slope with respect to temperature. The temperature dependence is best demonstrated in the graph of FIG. 5. In FIG. 5, the “pre-bake” P-Pa and U-Ua charge levels 22 and 24 (corresponding respectively to a logic one charge level and the logic zero charge level of a ferroelectric memory cell) are shown. Note that charge levels 22 and 24 have a generally negative slope with respect to temperature. This temperature dependency is also demonstrated in the same-state and opposite-state post bake charge levels 26, 28, 30, and 32. Note further in FIG. 5 that it is very difficult to construct a constant reference level 34 with respect to temperature that is lower than the lowest “logic one” charge level 26, 30, yet higher than the highest “logic zero” charge level 32. In other words, the margin of error over all temperatures is very small for a constant temperature prior art reference cell.

FIG. 5 shows how the P-Pa and U-Ua terms allow less margin for sensing after a retention bake. FIG. 5 also shows the negative temperature slope of the P-Pa and U-Ua terms. The prior art Da reference is plotted to show that the reference temperature slope does not match the array terms' temperature slopes. This data is measured from the Ramtron International Corporation FM30C256 ferroelectric memory device using the bit distribution mode. The desired reference is indicated by the goal reference line 36. This gives the most margin to sense after a retention bake, when the sense margin is the smallest.

What is desired, therefore, is a temperature-dependent reference circuit having a negative temperature coefficient that can provide optimum memory performance by “splitting the difference” over a wide temperature range between the temperature-dependent logic one and logic zero charge levels shown in FIG. 5. The ideal or goal reference target charge level trace 36 is shown in FIG. 5.

### SUMMARY OF THE INVENTION

According to the present invention, a temperature-dependent reference operates by pre-charging a standard linear CMOS or ferroelectric reference capacitor to a pre-charge voltage that is dependent on temperature. At cold temperatures the pre-charge voltage is higher, resulting in a larger voltage on the reference bit-line. At warm temperatures the pre-charge voltage is lower, resulting in a smaller voltage on the reference bit-line. Both the precise temperature slope and offset pre-charge voltage are selectable.

The present invention improves upon a standard 1T/1C “Da”-type reference scheme by better matching the temperature slope of the P-Pa logic one and U-Ua logic zero terms after a retention bake, when the sense margin is smallest. The standard Da-type reference has a flat bit-line voltage slope over temperature, but the memory array bits have a negative voltage slope over temperature with up/down sensing after a retention bake. This results in U-Ua sensing failures at cold temperatures and P-Pa sensing failures at high temperatures. This invention imparts the standard Da reference a negative voltage slope over temperature to closely match the voltage slope of the array bits.

The foregoing and other objects, features and advantages of the invention will become more readily apparent from the following detailed description of a preferred embodiment of the invention, which proceeds with reference to the accompanying drawings.

### BRIEF DESCRIPTION OF THE DRAWINGS

FIG. 1 is a hysteresis diagram for a ferroelectric capacitor illustrating the P, U, N, and D charge components;

FIG. 2 is a “Sawyer-Tower” circuit used for generating the hysteresis curve shown in FIG. 1;

FIG. 3 is a schematic diagram of a prior art “Da”-type reference cell for an integrated circuit ferroelectric memory;

FIG. 4 is a schematic diagram of a temperature-dependent reference cell circuit according to the present invention;

FIG. 5 is a plot of various charge components of a ferroelectric capacitor memory cell with respect to temperature, as well as prior art and goal reference voltages with respect to temperature;

FIG. 6 is a detailed transistor-level schematic diagram of the temperature-dependent circuitry in the reference cell according to the present invention; and

FIG. 7 is a plot of simulated reference cell performance according to the present invention over temperature.

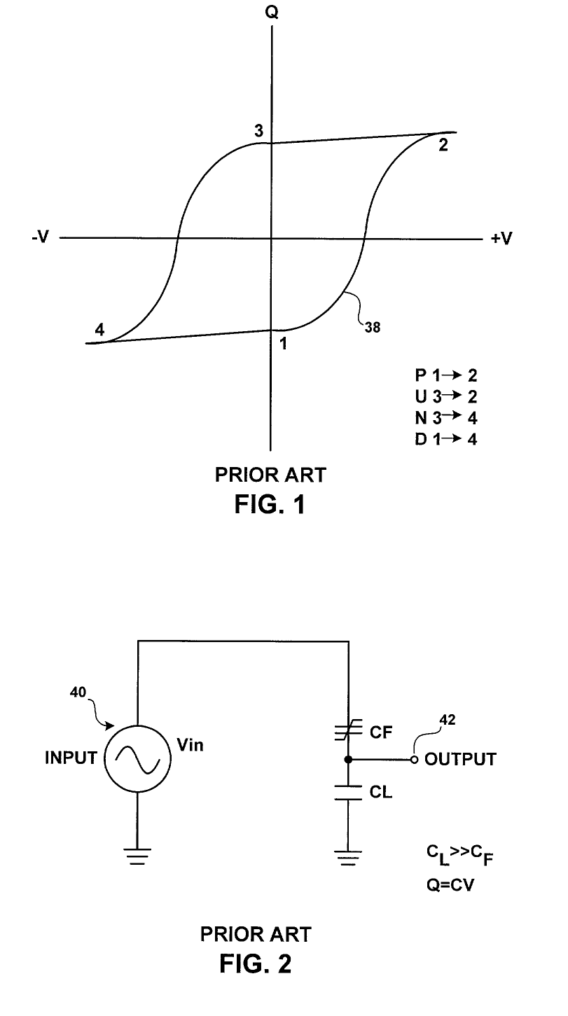

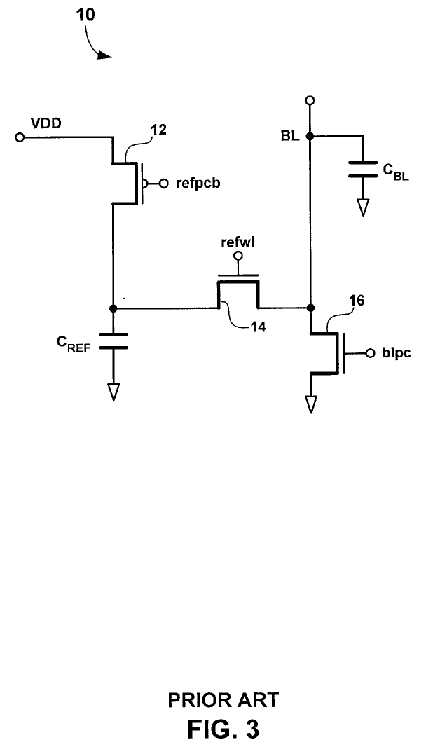

### DETAILED DESCRIPTION

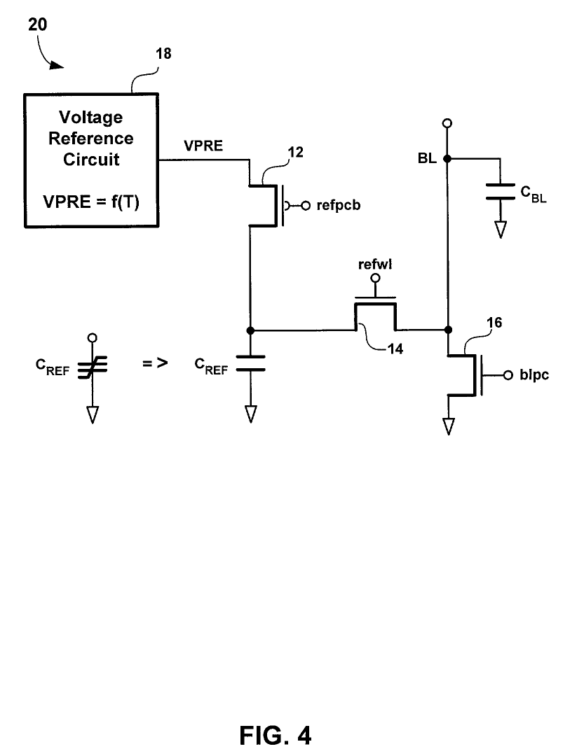

Referring generally now to FIG. 4, a schematic diagram of a temperature-dependent reference cell circuit 20 according to the present invention includes a voltage reference circuit 18 for generating a VPRE reference voltage. The VPRE reference voltage is a function of temperature. When reference cell circuit 20 is in a pre-charge state, the reference capacitor, CREF, is pre-charged to the temperature dependent VPRE level through the P-channel REFPCB device 12 and the N-channel REFWL device 14 is disabled. At the start of the access, the REFPCB device 12 is disabled and the REFWL device 14 is enabled so that the C_{REF} reference capacitor and the C_{BL} bit-line capacitance can share charge. Once the charge is shared, an intermediate-level temperature dependent reference voltage is produced on the bit-line, BL. N-channel transistor 16 enables the BL bit-line to be periodically grounded as required under the control of the BLPC control signal. In FIG. 4, the reference capacitor C_{REF} is preferably a ferroelectric capacitor used in the linear region or a standard CMOS linear capacitor.

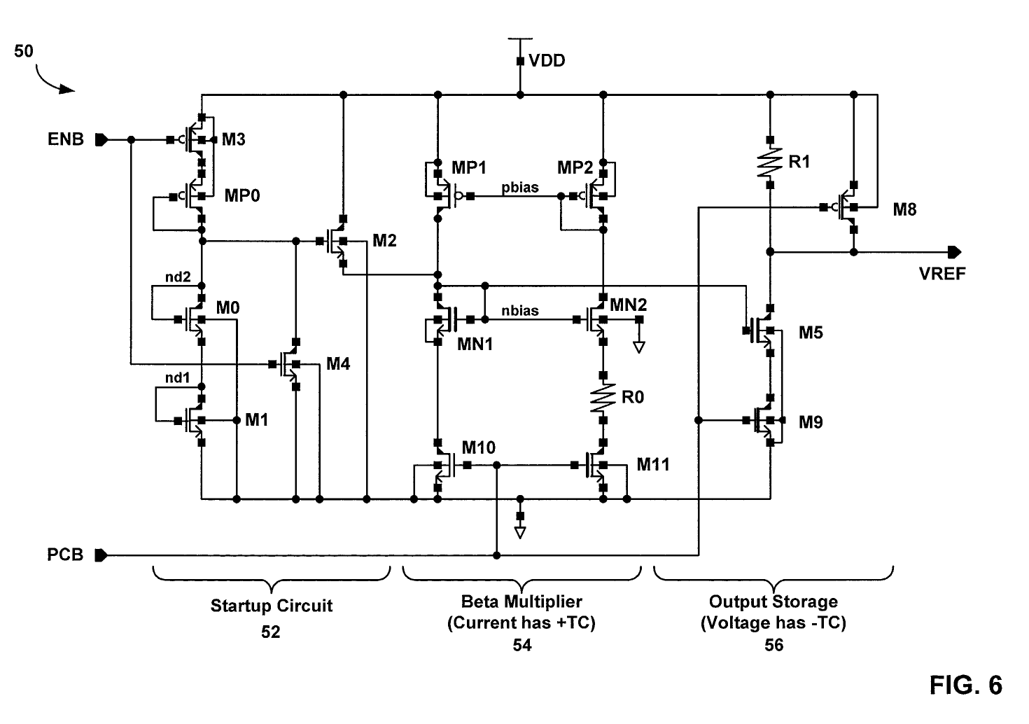

A temperature-adjusted pre-charge voltage reference circuit 50 is shown in FIG. 6, which corresponds to the circuit block 18 shown in FIG. 4. Reference circuit 50 is one implementation of a circuit that has the required negative voltage slope with respect to temperature. Reference circuit 50 includes a startup circuit 52, a beta multiplier circuit 54, which has the characteristic of increasing current with increasing temperature, and an output stage 56. The output stage 56 has the mirrored temperature dependent current with a resistor load that gives a strong negative voltage slope with increasing temperature. Startup circuit 52 provides the necessary biasing current for the beta multiplier circuit 54. The VREF output of circuit 50 is ideally buffered by a unity gain buffer amplifier (not shown in FIG. 6) to drive the large C_{REF} reference capacitor load.

The beta multiplier stage 54 includes a P-channel current mirror including transistors MP1 and MP2, an N-channel current mirror including transistors MN1 and MN2 coupled to the P-channel current mirror and a resistor R0 coupled to the N-channel current mirror. Resistor R0 can have an adjustable or programmable value for setting the temperature slope of the reference circuit as desired. The output stage 56 includes an N-channel transistor M5 having a gate coupled to the beta multiplier stage at the NBIAS node and a load coupled to the N-channel transistor. The load can be an adjustable or programmable value resistor R1, or a properly biased N-channel transistor M6 or P-channel transistor M7. Varying the value of resistor R1 or the biasing of an equivalent transistor load controls the output voltage offset at the VREF output node.

Transistors M8, M9, M10, and M11 are provide so that when the PCB node is held to ground, the VREF voltage is equal to the VDD supply voltage. When the PCB node is brought high, the VREF voltage is equal to the internally generated VREF voltage. Transistors M8, M9, M10, and M11, as well as the PCB signal form a pre-charging circuit for generating a reference capacitor pre-charge voltage, as is described in further detail below.

Several other circuits could be used instead of a beta multiplier, such as thermal voltage reference, diode reference, threshold voltage reference, etc. as long as their current changes predictably with temperature.

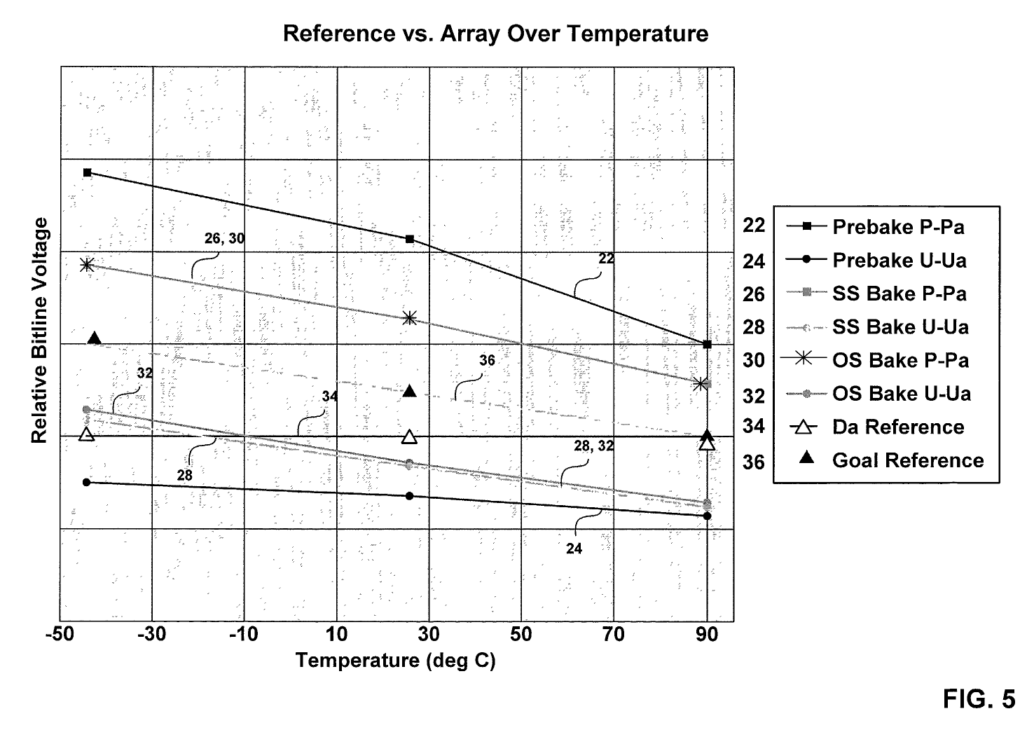

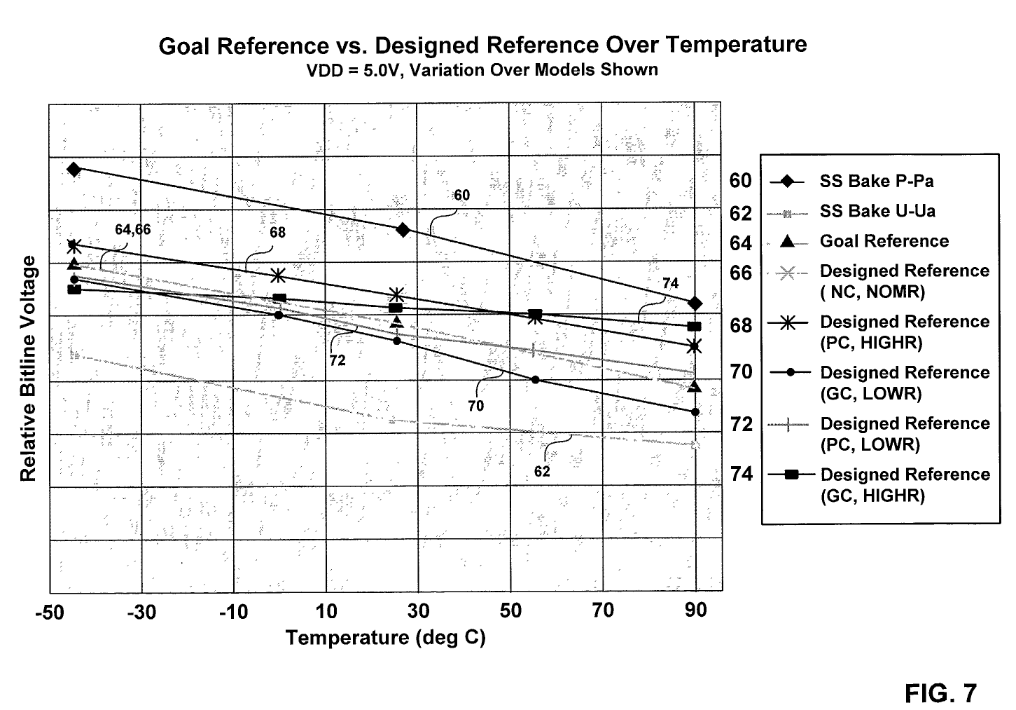

Referring now to FIG. 7, the simulated performance results of the reference cell according to the present invention are shown. FIG. 7 shows the results of computer simulations with nominal and corner models compared against the ideal goal reference and the worst case P-Pa and U-Ua terms from FIG. 5. The nominal case can be made to match almost exactly and are shown as a combined line 64, 66 in FIG. 7. The corner models deviate slightly from the goal, but still have the temperature slope in the correct direction. With trim options on the slope and offset resistors, the corner simulations can be modified to more closely track the goal reference.

In FIG. 7, traces 60 and 62 represent the logic one and logic zero same-state charge terms after bake. Traces 66, 68, 70, 72, and 74 represent various simulations results for the reference of the present invention wherein NC=normal case, PC=poor case CMOS transistors, GC=good case CMOS transistors, LOWR=low value resistor due to process variations, and HIGHR=high value resistor due to process variations.

If a ferroelectric reference capacitor's Da term is used, it may be advantageous to first pre-charge the reference capacitor to VDD before driving the pre-charge voltage, VPRE. This will help to ensure the circuit does not operate on a sub-loop with different temperature characteristics. A ferroelectric capacitor is desirable as the reference capacitor since its ferroelectric properties will closely match the properties of the array, which a CMOS reference capacitor will not do.

Having described and illustrated the principle of the invention in a preferred embodiment thereof, it is appreciated by those having skill in the art that the invention can be modified in arrangement and detail without departing from such principles. I therefore claim all modifications and variations coming within the spirit and scope of the following claims.

I claim:

1. A temperature-compensated reference circuit for an integrated circuit 1T/1C ferroelectric memory comprising:
a reference capacitor;
an active circuit for providing a negative voltage slope with respect to temperature;
means for selectively coupling the reference circuit to the reference capacitor; and
means for selectively coupling the reference capacitor to a bit line.

2. The reference circuit of claim 1 in which the reference capacitor comprises a linear capacitor.

3. The reference circuit of claim 1 in which the reference capacitor comprises a ferroelectric capacitor.

4. The reference circuit of claim 1 in which the means for selectively coupling the reference circuit to the reference capacitor comprises a P-channel transistor having a gate for receiving a control signal.

5. The reference circuit of claim 1 in which the means for selectively coupling the reference capacitor to the bit line comprises an N-channel transistor having a gate for receiving a control signal.

6. The reference circuit of claim 1 in which the active circuit comprises:
a beta multiplier stage; and
an output stage coupled to the beta multiplier stage.

7. The reference circuit of claim 6 further comprising a startup circuit coupled to the beta multiplier stage.

8. The reference circuit of claim 6 in which the beta multiplier stage comprises:
a P-channel current mirror;
an N-channel current mirror coupled to the P-channel current mirror; and
a resistor coupled to the N-channel current mirror.

9. The reference circuit of claim 8 in which the resistor comprises an adjustable or programmable value resistor.

10. The reference circuit of claim 6 in which the output stage comprises:
an N-channel transistor having a gate coupled to the beta multiplier stage; and
a load coupled to the N-channel transistor.

11. The reference circuit of claim 10 in which the load comprises an adjustable or programmable value resistor.

12. The reference circuit of claim 10 in which the load comprises an N-channel transistor.

13. The reference circuit of claim 10 in which the load comprises a P-channel transistor.

14. The reference circuit of claim 1 in which the active circuit comprises:
a positive temperature coefficient stage; and
a negative temperature coefficient output stage coupled to the positive temperature coefficient stage.

15. The reference circuit of claim 14 further comprising a startup circuit coupled to the positive temperature coefficient stage.

16. The reference circuit of claim 14 in which the positive temperature coefficient stage comprises an adjustable or programmable positive temperature coefficient.

17. The reference circuit of claim 14 in which the negative temperature coefficient output stage comprises an output stage having an adjustable or programmable absolute value output voltage.

18. The reference circuit of claim 1 further comprising a circuit for pre-charging the reference capacitor.

19. The reference circuit of claim 18 in which the pre-charging circuit includes first, second, third, and fourth transistors each having a gate for receiving a pre-charge signal.

20. A method for providing a temperature-compensated reference circuit for an integrated circuit 1T/1C ferroelectric memory comprising:
providing a reference capacitor;
providing a negative voltage slope with respect to temperature;
selectively coupling the reference circuit to the reference capacitor; and
selectively coupling the reference capacitor to a bit line.
